(19) United States
(12) Patent Application Publication
(10) Pub. No.: US 2006/0063296 A1
(43) Pub. Date: Mar. 23, 2006

(54) Method of forming nanoparticle oxide electrode of plastic-type dye-sensitized solar cell using high viscosity nanoparticle oxide paste without binder

(76) Inventors: Nam Gyu Park, Daejeon-city (KR); Mangu Kang, Daejeon-city (KR); Kwang Man Kim, Daejeon-city (KR); Kwang Sun Ryu, Daejeon-city (KR); Soon Ho Chang, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/146,494

(22) Filed: Jun. 6, 2005

(30) Foreign Application Priority Data
Sep. 23, 2004 (KR) 10-2004-0076426

(51) Int. Cl. H01L 31/00

(52) U.S. Cl. 438/93; 136/252

(57) ABSTRACT

A method for forming a nanoparticle oxide electrode of a dye-sensitized solar cell is provided. In the method, a basic aqueous solution or an acidic aqueous solution is respectively added to a nanoparticle oxide colloidal solution having a good acidic or basic dispersion, to form a basic nanoparticle oxide paste by an acid-base reaction. Next, after the nanoparticle oxide paste is coated on a substrate, the coated nanoparticle oxide paste is dried at a low temperature of 150° C. or lower. Accordingly, the low-temperature coating nanoparticle oxide paste with high viscosity can be manufactured on the basis of the acid-base reaction, even without the addition of polymer, and accordingly, the nanoparticle oxide electrode can be formed even at a low temperature.

### CROSS-REFERENCE TO RELATED PATENT APPLICATIONS

This application claims the benefit of Korean Patent Application No. 10-2004-0076426, filed on Sep. 23, 2004, in the Korean Intellectual Property Office, the disclosure of which is incorporated herein in its entirety by reference.

### BACKGROUND OF THE INVENTION

1. Field of the Invention

The present invention relates to a method of manufacturing a plastic-type dye-sensitized solar cell, and more particularly, to a method of forming a nanoparticle oxide electrode of a plastic-type dye-sensitized solar cell.

2. Description of the Related Art

A dye-sensitized solar cell is a photoelectrochemical solar cell made public by Gratzel, et al., of Switzerland in 1991. The dye-sensitized solar cell is being highlighted as a next generation solar cell to replace the conventional silicon solar cell due to its low price and energy conversion efficiency of 10%. The dye-sensitized solar cell includes a conductive electrode formed of nanoparticle oxide which absorbs dye molecules, a counter electrode coated with platinum, carbon or the like, and an iodine oxidation-reduction electrolyte.

Generally, the conductive electrode of the dye-sensitized solar cell is formed of a nanoparticle titanium oxide on a transparent conductive glass substrate, as follows.

After a nanoparticle titanium oxide colloidal solution is prepared, polymer is mixed with the nanoparticle titanium oxide colloidal solution to form a titanium oxide paste with high viscosity. Next, the titanium oxide paste is coated on the transparent conductive glass substrate, and heat-treated at a high temperature of 450° C. to 500° C. for about 30 minutes in an air or oxygen atmosphere to form the nanoparticle titanium oxide electrode.

The reason why the titanium oxide paste is heat-treated at 400° C. or higher is to burn and eliminate the polymer, to improve adhesion between the nanoparticles and the glass substrate, and to allow the necking or interconnection of the nanoparticles. The nanoparticle titanium oxide electrode manufactured at 400° C. or higher has an excellent nanoparticle interconnection and accordingly, an excellent photoelectric transformation.

However, a flexible dye-sensitized solar cell is required. Accordingly, the nanoparticle titanium oxide electrode must be formed on a conductive plastic substrate. For this, the titanium oxide electrode must be formed at a temperature tolerable by the plastic substrate, for example, 150° C. or lower for polyethylene terephthalate (PET). The titanium oxide electrode must still have excellent nanoparticle interconnection.

As a result, the above-described high-temperature coating titanium oxide paste cannot be coated on the plastic substrate, since it must be dried at a high temperature. A low-temperature coating titanium oxide paste, to which polymer is not added, is required to manufacture the nanoparticle titanium oxide electrode having the excellent nanoparticle interconnection even at a low temperature.

Most currently known low-temperature coating titanium oxide pastes are manufactured by dispersing the nanoparticle titanium oxide in water or alcohol. Therefore, it is difficult to control the viscosity of the titanium oxide paste, and therefore difficult to control the thickness of the titanium oxide electrode. Further, when the conventional titanium oxide paste is manufactured using only water or alcohol, it is difficult to achieve the nanoparticle interconnection at a low temperature.

### SUMMARY OF THE INVENTION

The present invention provides a method for forming a nanoparticle oxide electrode of a plastic-type dye-sensitized solar cell using a nanoparticle oxide paste, which can be coated at a low temperature of 150° C. or lower and has an excellent interconnection of nanoparticles.

According to an aspect of the present invention, there is provided a method for forming a nanoparticle oxide electrode of a plastic-type dye-sensitized solar cell, the method including: preparing a nanoparticle oxide colloidal solution having a good acidic or basic dispersion; respectively adding a basic aqueous solution or an acidic aqueous solution to the nanoparticle oxide colloidal solution having good acidic or basic dispersion, to form a basic nanoparticle oxide paste by an acid-base reaction; coating the nanoparticle oxide paste on a substrate; and drying the coated nanoparticle oxide paste.

Nanoparticle oxide contained in the nanoparticle oxide colloidal solution having good acidic dispersion may be selected from the group consisting of titanium oxide (TiO₂), zinc oxide (ZnO) and niobium oxide (Nb₂O₅). Nanoparticle oxide contained in the nanoparticle oxide colloidal solution having good basic dispersion may be selected from the group consisting of tin oxide (SnO₂) and tungsten oxide (WO₃).

Basic material contained in the basic aqueous solution may be material that can be dissociated in water to give hydroxyl ions.

Acidic material contained in the acidic aqueous solution may be material that can be dissociated in water to give hydrogen ions.

The substrate may be a conductive plastic substrate, a conductive glass substrate, a conductive metal substrate, a semiconductor substrate or an insulating substrate. The coated nanoparticle oxide paste can be dried in an air atmosphere, an oxygen atmosphere, a nitrogen atmosphere, an argon atmosphere or a vacuum atmosphere, at between room temperature and 150° C.

As described above, the present invention allows the manufacture of a low-temperature coating nanoparticle oxide paste with a high viscosity on the basis of the acid-base reaction, even without the addition of polymer, and accordingly can form the nanoparticle oxide electrode even at a low temperature.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart illustrating a method for forming a nanoparticle oxide electrode of a plastic-type dye-sensitized solar cell according to an embodiment of the present invention;

FIG. 2 is a graph illustrating photocurrent density-voltage characteristics depending on the thickness of a nanoparticle oxide electrode of a plastic-type dye-sensitized solar cell according to the present invention;

FIG. 3 is a graph illustrating an incident-photon-to-current efficiency (IPCE) depending on the thickness of a nanoparticle oxide electrode of a plastic-type dye-sensitized solar cell according to the present invention; and

FIG. 4 is a graph illustrating photocurrent density-voltage characteristics depending on post-treatment conditions of a nanoparticle oxide electrode of a plastic-type dye-sensitized solar cell according to the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

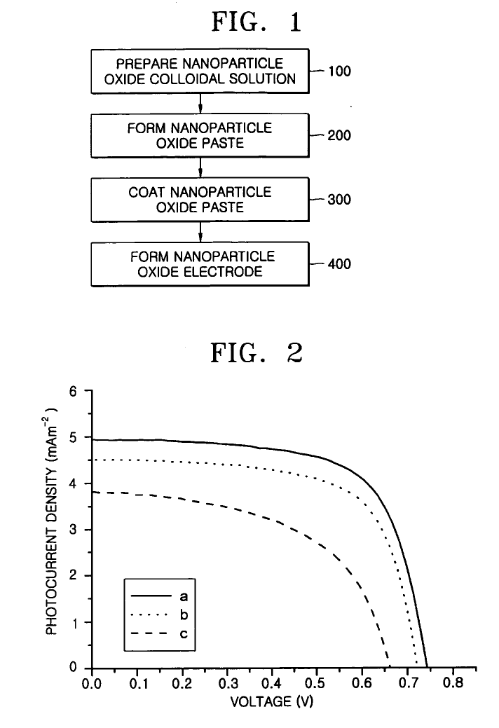

FIG. 1 is a flowchart illustrating a method for forming a nanoparticle oxide electrode of a plastic-type dye-sensitized solar cell according to an embodiment of the present invention.

A nanoparticle oxide colloidal solution is prepared (S100). At this time, the nanoparticle oxide colloidal solution is prepared using nanoparticle oxide having a good acidic or basic dispersion.

Titanium oxide (TiO₂), zinc oxide (ZnO), and niobium oxide (Nb₂O₅) are examples of nanoparticle oxides having good acidic dispersion. Silicon oxide (SiO₂) and tungsten oxide (WO₃) are examples of nanoparticle oxides having good basic dispersion.

Next, a basic aqueous solution or an acid aqueous solution is added to the nanoparticle oxide colloidal solution, depending on the acidic or basic dispersion of the colloidal solution used, to manufacture a basic nanoparticle oxide paste on the basis of an acid-base reaction (S200).

Here, in the case that the nanoparticle oxide has good acidic dispersion, the basic aqueous solution is added. In the case that the nanoparticle oxide has good basic dispersion, the acidic aqueous solution is added.

The basic aqueous solution can be organic or inorganic material which can be dissociated in water to give hydroxyl ions (OH—). The acidic aqueous solution can be organic or inorganic material which can be dissociated in water to give hydrogen ions (H—). Ammonia is an example of the basic material, and acetic acid, nitric acid, hydrochloric acid, and phosphoric acid are examples of the acidic material.

The viscosity of the nanoparticle oxide paste can be increased by the acid-base reaction, even though no polymer is added as in the conventional art. For example, if an ammonium hydroxide (NH₄OH) alkali aqueous solution is added to a nanoparticle titanium oxide (TiO₂) acidic colloidal solution, a high viscosity of 60,000 through 120,000 cP is obtained, as measured by a “Brookfield Model DV-III (spindle #94)” viscometer. At this time, the nanoparticle titanium oxide (TiO₂) has an average particle diameter of about 20 to 30 nm, and the weight ratio of ammonium hydroxide (NH₄OH) to titanium oxide (TiO₂) is 0.015 to 0.3. Of course, this nanoparticle oxide paste can be subsequently dried at a low temperature, for example, 150° C. or lower, since no polymer is added.

After that, the nanoparticle oxide paste is coated on a substrate by a doctor blade method (S300). The substrate can not only be a conductive plastic substrate, but also a conductive glass substrate, a conductive metal substrate, a semiconductor substrate or an insulating substrate.

Next, the coated nanoparticle oxide paste is dried to form the nanoparticle oxide electrode (S400). The drying can be performed in an air atmosphere, an oxygen atmosphere, a nitrogen atmosphere, an argon atmosphere or a vacuum atmosphere. The drying can be performed not only at a room temperature to a low temperature of 150° C. or lower, but also at a room temperature to 500° C. The nanoparticle oxide electrode is easily formed up to a thickness of 15 μm through 20 μm without cracking, by using the nanoparticle oxide paste.

Hereinafter, an exemplary method is described for forming the nanoparticle oxide electrode of the dye-sensitized solar cell, using a titanium oxide paste or a tin oxide paste as the nanoparticle oxide paste.

### EXPERIMENTAL EXAMPLE 1

An example of a method for forming the nanoparticle oxide electrode of the dye-sensitized solar cell using the titanium oxide paste is described.

Titanium isopropoxide, acetic acid, isopropanol and water are reacted at a temperature of 230° C. for 12 hours to prepare the titanium oxide (TiO₂) colloidal solution by a hydrothermal composite method.

A solvent is evaporated from the titanium oxide colloidal solution to obtain a colloidal solution with titanium oxide having a particle size of about 5 nm to 30 nm, until the concentration of titanium oxide is 5 wt % to 15 wt %, and preferably 12 wt % to 13 wt %, of the obtained titanium oxide colloidal solution. As described above, the titanium oxide contained in the titanium oxide colloidal solution is a nanoparticle oxide having good acidic dispersion.

After that, 1 to 10 moles of ammonia (NH₃) aqueous solution are added and agitated with a magnetic stirrer in 10 g of the titanium oxide colloidal solution concentrated to 12.5 wt %, so that the weight ratio of titanium oxide (TiO₂) to ammonium hydroxide (NH₄OH) is 0.01 to 0.5 (that is, 0.01<NH₄OH/TiO₂<0.5 and preferably, 0.01<NH₄OH/TiO₂<0.1). As the ammonia aqueous solution is added, the titanium oxide colloidal solution becomes the basic nanoparticle titanium oxide paste depending on the acid-base reaction. The ammonia aqueous solution is a basic aqueous solution. Ammonia contained in the ammonia aqueous solution can be dissociated in water to give hydroxyl ions (OH—). In addition to ammonia, organic or inorganic basic material can be also used.

Next, the nanoparticle titanium oxide electrode is formed by coating the titanium oxide paste on the substrate by the doctor blade method.

### EXPERIMENTAL EXAMPLE 2

An example of a method for forming the nanoparticle oxide electrode of the dye-sensitized solar cell by using the tin oxide paste is described.

A tin oxide colloidal solution is prepared in a hydrothermal composite method. A solvent is evaporated from the tin oxide colloidal solution to obtain a colloidal solution with tin oxide having a size of about 5 nm to 30 nm, until the concentration of the tin oxide is 5 wt % to 15 wt %, and preferably 12 wt % to 13 wt %, of the obtained tin oxide colloidal solution. As described above, the tin oxide contained in the tin oxide colloidal solution is a nanoparticle oxide having good basic dispersion.

After that, 1 to 10 moles of acetic acid (CH₃COOH) aqueous solution are added and agitated with a magnetic stirrer in 10 g of the tin oxide colloidal solution concentrated to 12.5 wt %, so that the weight ratio of ammonium hydroxide (NH₄OH) to tin oxide (SnO₂) is 0.01 to 0.5 (that is, 0.01<NH₄OH/SnO₂<0.5 and preferably, 0.01<NH₄OH/SnO₂<0.1). As the acetic acid aqueous solution is added, the tin oxide colloidal solution becomes the basic nanoparticle tin oxide paste by the acid-base reaction. The acetic acid aqueous solution is the acidic aqueous solution. Acetic acid contained in the acetic acid aqueous solution can be dissociated in water to give hydrogen ions (H+). In addition to acetic acid, organic or inorganic acidic material can be also used.

Next, after the tin oxide paste is coated on the substrate using the doctor blade method, the coated tin oxide paste is dried to form the nanoparticle titanium oxide electrode.

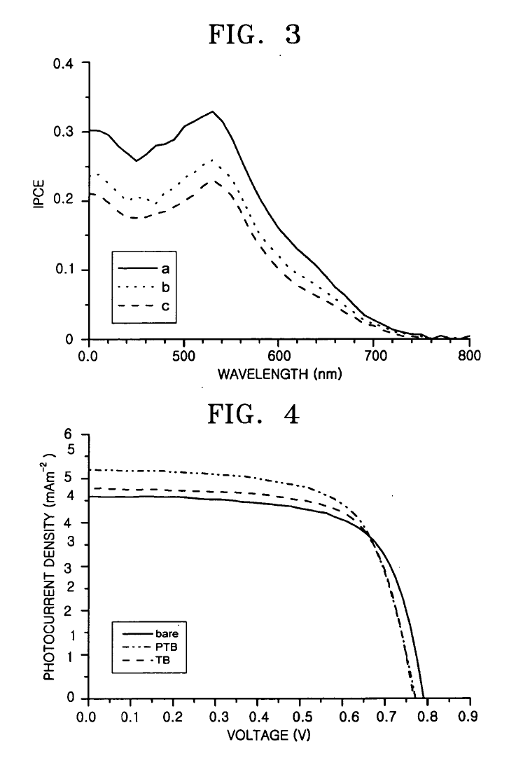

FIG. 2 is a graph illustrating photocurrent density-voltage characteristics depending on the thickness of the nanoparticle oxide electrode of the plastic-type dye-sensitized solar cell according to the present invention, and FIG. 3 is a graph illustrating an incident-photon-to-current efficiency (IPCE) depending on the thickness of the nanoparticle oxide electrode of the plastic-type dye-sensitized solar cell according to the present invention.

This nanoparticle oxide electrode employs the nanoparticle oxide electrode manufactured through Experimental example 1. In FIGS. 2 and 3, “a”, “b” and “c” denote experimental results using nanoparticle titanium oxide electrodes respectively having a thickness of 5.4 μm, 8.5 μm and 12.7 μm. In Table 1, current density (Jsc), voltage (Voc), fill factor (FF) and energy conversion efficiency (Eff.) depending on the thickness of the titanium oxide electrode of the dye-sensitized solar cell are arranged with reference to FIG. 2. “Jsc” denotes the photocurrent density in a short circuit, that is, at a voltage of 0V. “Voc” denotes the voltage at an open circuit, that is, a current density of zero.

TABLE 1

| Electrode | | | | |
|---|---|---|---|---|
| thickness (μm) | Jsc (mA/cm²) | Voc (V) | FF (%) | Eff. (%) |
| 5.4 | 4.94 | 0.74 | 0.67 | 2.45 |
| 8.5 | 4.51 | 0.72 | 0.67 | 2.18 |
| 12.7 | 3.82 | 0.66 | 0.54 | 1.36 |

As shown in Table 1, the titanium oxide electrode having a thickness of 5.4 μm has an energy conversion efficiency of 2.45%. This is the best in comparison with other research results under similar conditions. The titanium oxide electrodes having a thickness of 5.4 μm and 8.5 μm have an excellent fill factor of 67%. This shows that the nanoparticle interconnection is excellent. Further, as shown in FIG. 3, it can be appreciated that as the titanium oxide electrode is increased in thickness, its energy conversion efficiency is decreased. This shows that long-wavelength light energy is not used effectively.

FIG. 4 is a graph illustrating photocurrent density-voltage characteristics depending on post-treatment conditions of the nanoparticle oxide electrode of the plastic-type dye-sensitized solar cell according to the present invention.

This nanoparticle oxide electrode employs the nanoparticle titanium oxide electrode manufactured through Experimental example 1. After the nanoparticle titanium oxide electrode was formed as in Experimental example 1, it was post-treated using 1 mM to 10 mM of a titanium butoxide (TB) isopropanol solution, and 0.1 wt % to 5 wt % of a poly titanium butoxide (PTB) isopropanol solution. As the result of the post-treatment, the current increased slightly compared with the untreated sample (denoted as “bare” in FIG. 4), but the fill factor was similar before and after post-treatment.

This shows that there is no great variation in the energy conversion efficiency before and after the treatment of an alkoxide-based molecule. This weak effect of the post-treatment shows that the nanoparticle interconnection of the basic titanium oxide paste is excellent even when formed at lower temperatures, and even without the assistance of bridging molecules such as alkoxide, since an acid-base bond is already created at the low temperature.

As described above, the present invention allows the manufacture of a low-temperature coating nanoparticle oxide paste with a high viscosity on the basis of the acid-base reaction, even though no polymer is added.

The high viscosity basic oxide paste can be coated on the substrate by the doctor blade method, and the coated nanoparticle oxide paste can be dried to easily and uniformly form a nanoparticle oxide electrode up to a thickness of 15 μm to 20 μm without cracking.

Specifically, the nanoparticle oxide paste according to the present invention can be dried at a low temperature of 150° C. or lower to form a nanoparticle oxide electrode having excellent nanoparticle interconnection.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a nanoparticle oxide electrode of a plastic-type dye-sensitized solar cell, the method comprising:
preparing a nanoparticle oxide colloidal solution having a good acidic or basic dispersion;
respectively adding a basic aqueous solution or an acidic aqueous solution to the nanoparticle oxide colloidal solution having a good acidic or basic dispersion, to form a basic nanoparticle oxide paste by an acid-base reaction;
coating the nanoparticle oxide paste on a substrate; and
drying the coated nanoparticle oxide paste.

2. The method according to claim 1, wherein nanoparticle oxide which is contained in the nanoparticle oxide colloidal solution having good acidic dispersion is selected from the group consisting of titanium oxide (TiO₂), zinc oxide (ZnO) and niobium oxide (Nb₂O₅).

3. The method according to claim 1, wherein nanoparticle oxide which is contained in the nanoparticle oxide colloidal solution having good basic dispersion is selected from the group consisting of tin oxide (SnO₂) and tungsten oxide (WO₃).

4. The method according to claim 1, wherein basic material which is contained in the basic aqueous solution to add the acidic nanoparticle oxide colloidal solution is organic or inorganic material that can be dissociated in water to give hydroxyl ions.

5. The method according to claim 1, wherein acidic material which is contained in the acidic aqueous solution to add the basic nanoparticle oxide colloidal solution is organic or inorganic material that can be dissociated in water to give hydrogen ions.

6. The method according to claim 1, wherein the substrate is a conductive plastic substrate, a conductive glass substrate, a conductive metal substrate, a semiconductor substrate or an insulating substrate.

7. The method according to claim 1, wherein the nanoparticle oxide paste is coated on the substrate by a doctor blade method.

8. The method according to claim 1, wherein the coated nanoparticle oxide paste is dried in an air atmosphere, an oxygen atmosphere, a nitrogen atmosphere, an argon atmosphere or a vacuum atmosphere, and at between room temperature and 150° C.

9. A method of forming a nanoparticle oxide electrode of a plastic-type dye-sensitized solar cell, the method comprising:
preparing a titanium oxide (TiO₂) colloidal solution;
adding an ammonia (NH₃) aqueous solution to the titanium oxide colloidal solution to form a basic nanoparticle titanium oxide paste by an acid-base reaction;
coating the titanium oxide paste on a substrate; and
drying the coated nanoparticle titanium oxide paste at between room temperature and 150° C.

10. A method of forming a nanoparticle oxide electrode of a plastic-type dye-sensitized solar cell, the method comprising:
preparing a tin oxide (SnO₂) colloidal solution;
adding an acetic acid aqueous solution to the tin oxide colloidal solution to form a basic nanoparticle tin oxide paste by an acid-base reaction;
coating the tin oxide paste on a substrate; and
drying the coated nanoparticle tin oxide paste at between room temperature and 150° C.
